(19) United States
(12) Patent Application Publication
(10) Pub. No.: US 2021/0066830 A1
(43) Pub. Date: Mar. 4, 2021

(54) STRIPLINE EDGE SNAP RADIO-FREQUENCY CONNECTION

(71) Applicant: RAYTHEON COMPANY, Waltham, MA (US)

(72) Inventors: Kevin Wilder, Derry, NH (US); Alan C. Smith, San Jose, IL (US); James Benedict, Tewksbury, MA (US); Andrew Southworth, Lowell, MA (US); Thomas V. Sikina, Acton, MA (US); Mary K. Herndon, Littleton, MA (US); John P. Haven, Lowell, MA (US)

(21) Appl. No.: 16/552,694

(22) Filed: Aug. 27, 2019

(51) Int. Cl. H01R 12/71; H05K 1/02; H05K 1/14; H05K 3/36; H01R 12/70; H01R 43/20; H01R 43/26

(52) U.S. Cl. CPC H01R 12/714; H05K 1/0237; H05K 1/142; H05K 2201/093; H01R 12/7005; H01R 43/205; H01R 43/26; H05K 3/36

(57) ABSTRACT

A stripline radio-frequency (RF) connection interface is provided and includes first and second printed circuit boards (PCBs). The first PCB includes a first trace, ground planes at opposite sides of the first trace, dielectric material interposed between the first trace and the ground planes and a first end. The first end is formed as a first rabbet at which the first trace is exposed. The second PCB includes a second trace, ground planes at opposite sides of the second trace, dielectric material interposed between the second trace and the ground planes and a second end. The second end is formed as a second rabbet, which is substantially identical to the first rabbet, at which the second trace is exposed. The first and second ends are mated in a shiplap joint to electrically couple the first and second traces.

### BACKGROUND

The present disclosure relates to an apparatus and methods for providing board-to-board radio-frequency (RF) connections and, in particular, to an apparatus and methods for providing a connection interface for board-to-board connections without coaxial connectors.

RF Connectors are currently used to make connections between printed circuit boards (PCBs). Such RF connectors are traditionally precision machined from corrosion resistant materials and, because of this, the RF connectors tend to be one of the largest cost drivers on RF PCBs. In addition, cable interfaces are sometimes required, which drive further costs, and RF connectors are typically installed by a solder reflow process, or manually, which leads to unnecessary processing time and assembly costs. Also, RF connectors are usually attached on the top surface or on the side of a PCB, which prevents those PCBs from being stacked in a spatially efficient manner.

In particular, contemporary RF connections can be expensive, tend to consume valuable space on PCBs and add complexity. Standard RF connector cost is introduced at many levels: the phase during which RF connectors are selected, RF interface design phases, surface mount part assembly phases, inspection phases and mating connector installation phases. In terms of standard RF connectors consuming valuable space, it has been observed that RF connectors tend to set board-to-board spacing in that they can prevent multiple board arrangements and can lead to core PCB stack-ups, they require that space be allocated for connector assemblies and post-assembly inspection. In terms of standard RF connectors adding complexity, it has been observed that they require integrated electrical-mechanical PCB design stages, lead to the provision of multi-core PCBs, can require the use of solder reflow during PCB assembly just for RF connectors and can tend towards high unit cell count line replaceable units (LRUs) that in turn require high yields.

### SUMMARY

According to an aspect of the disclosure, a stripline radio-frequency (RF) connection interface is provided and includes first and second printed circuit boards (PCBs). The first PCB includes a first trace, ground planes at opposite sides of the first trace, dielectric material interposed between the first trace and the ground planes and a first end. The first end is formed as a first rabbet at which the first trace is exposed. The second PCB includes a second trace, ground planes at opposite sides of the second trace, dielectric material interposed between the second trace and the ground planes and a second end. The second end is formed as a second rabbet, which is substantially identical to the first rabbet, at which the second trace is exposed. The first and second ends are mated in a shiplap joint to electrically couple the first and second traces.

In accordance with additional or alternative embodiments, the ground planes of the first and second PCBs each include conductive material.

In accordance with additional or alternative embodiments, the first and second traces are each formed as striplines.

In accordance with additional or alternative embodiments, a conductive material is electrically interposed between the first and second traces.

In accordance with additional or alternative embodiments, one or more fasteners fasten the first and second ends together.

In accordance with additional or alternative embodiments, one or more magnetic elements magnetically attract the first and second ends together.

In accordance with additional or alternative embodiments, an external mechanical force forces the first and second ends together.

According to another aspect of the disclosure, a radio-frequency (RF) circuit assembly is provided and includes a plurality of printed circuit boards (PCBs). Each PCB of the plurality of PCBs includes a trace, ground planes at opposite sides of the trace, dielectric material interposed between the trace and the ground planes and an end. The end is formed as a rabbet at which the trace is exposed. The end of each PCB of the plurality of PCBs is mated in a shiplap joint with an end formed as a substantially identical rabbet of a neighboring PCB such that the corresponding traces are electrically coupled.

In accordance with additional or alternative embodiments, the plurality of PCBs includes first and second exterior PCBs including lead terminals, first and second interior PCBs mated with one another and including electrical devices and first and second intermediate PCBs mated in sequence with the first and second exterior PCBs, respectively, with one another, respectively, and with the first and second interior PCBs, respectively.

In accordance with additional or alternative embodiments, the ground planes of each PCB of the plurality of PCBs each include conductive material.

In accordance with additional or alternative embodiments, the trace of each PCB of the plurality of PCBs is formed as a stripline.

In accordance with additional or alternative embodiments, a conductive material is electrically interposed between the traces of neighboring PCBs.

In accordance with additional or alternative embodiments, one or more fasteners fasten respective ends of neighboring PCBs together.

In accordance with additional or alternative embodiments, one or more magnetic elements magnetically attract respective ends of neighboring PCBs together.

In accordance with additional or alternative embodiments, an external mechanical force forces respective ends of neighboring PCBs together.

According to another aspect of the disclosure, a method of assembling a stripline radio-frequency (RF) connection interface is provided. The method includes assembling a first printed circuit board (PCB) to comprise a first trace, ground planes at opposite sides of the first trace and dielectric material interposed between the first trace and the ground planes, assembling a second PCB to comprise a second trace, ground planes at opposite sides of the second trace and dielectric material interposed between the second trace and the ground planes, forming complementary ends of the first and second PCBs as first and second substantially identical rabbets, respectively, at which the first and second traces are exposed, respectively, and mating the complementary ends of the first and second PCBs in a shiplap joint to electrically couple the first and second traces.

In accordance with additional or alternative embodiments, the method further includes electrically interposing conductive material between the first and second traces.

In accordance with additional or alternative embodiments, the method further includes fastening the complementary ends of the first and second PCBs together.

In accordance with additional or alternative embodiments, the method further includes magnetically attracting the complementary ends of the first and second PCBs together.

In accordance with additional or alternative embodiments, the method further includes applying an external mechanical force to force the complementary ends of the first and second PCBs together.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

For a more complete understanding of this disclosure, reference is now made to the following brief description, taken in connection with the accompanying drawings and detailed description, wherein like reference numerals represent like parts:

FIG. 1 is a top down view of an assembly process for a stripline SNAP-RF connection in accordance with embodiments;

FIG. 2 is a side view of an assembly process for a stripline SNAP-RF connection in accordance with embodiments;

FIG. 3 is a perspective view of an assembly process for a stripline SNAP-RF connection in accordance with embodiments;

FIG. 4 is a side view of an assembled stripline SNAP-RF connection in accordance with embodiments;

FIG. 5 is a top down schematic illustration of an RF circuit assembly in accordance with embodiments;

FIG. 6 is a flow diagram illustrating a method of assembling a stripline radio-frequency (RF) connection interface in accordance with embodiments; and

FIG. 7 is an illustration of the method of FIG. 6 in accordance with embodiments.

### DETAILED DESCRIPTION

As will be described below, a stripline SNAP-RF connection interface is provided and enables board-to-board RF connections without the use of RF connectors, electroplating and vias. The stripline SNAP-RF connection reduces costs and complexity of RF panels by eliminating the need for traditional connectors, one of the main cost drivers of traditional RF panels. The stripline SNAP-RF connection does not require solder reflow, and can be easily integrated into the PCB manufacturing processes without a placement line. In addition, while traditional connectors tend to have significant losses and tend to have relatively high height profiles above board surfaces and thus pose packaging problems in tight areas, the stripline SNAP-RF connection exhibits reduced loss characteristics and has a flat profile.

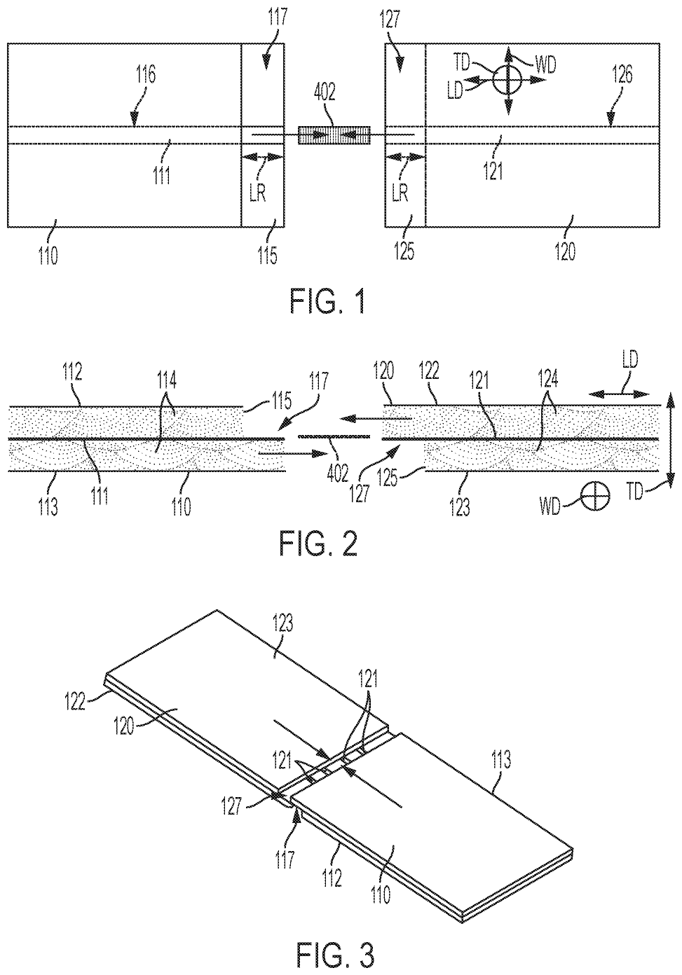

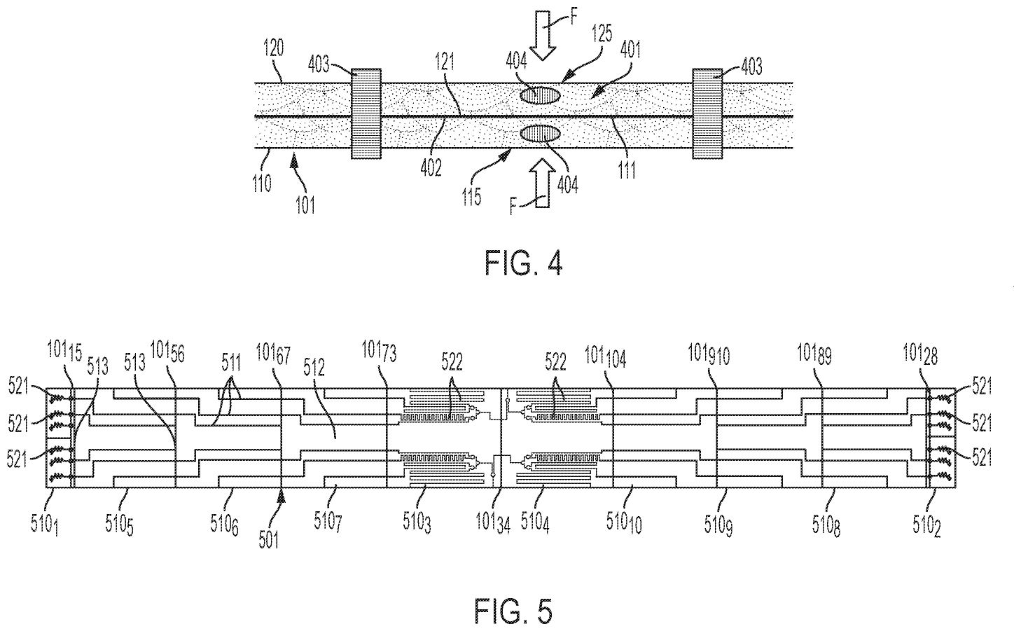

With reference to FIGS. 1-4, a stripline SNAP-RF connection interface 101 (see FIG. 4) is provided and includes a first PCB 110 and a second PCB 120.

The first PCB 110 includes a first circuit trace 111, first and second ground planes 112 and 113 (see FIG. 2) at opposite sides of the first circuit trace 111, dielectric material 114 interposed between the first circuit trace 111 and the first and second ground planes 112 and 113 at the opposite sides of the first circuit trace 111 and a first end 115. The first circuit trace 111 can be formed of conductive material (e.g., copper, tin, etc.) and can be formed with a stripline shape 116 having a relative small thickness in the thickness dimension TD, a width in the width dimension WD that exceeds the relatively small thickness and a length in the length dimension LD that exceeds the width. The first and second ground planes 112 and 113 can be formed with conductive material (e.g., copper, tin, etc.) and can be substantially flat and planar. The dielectric material 114 electrically isolates the first circuit trace 111 between the first and second ground planes 112 and 113. The first end 115 is characterized in that an end of the first ground plane 112 and the dielectric material 114 between the first ground plane 112 and the first circuit trace 111 are recessed from respective corresponding ends of the first circuit trace 111 and the second ground plane 113 to thus form the first end 115 into a first rabbet 117 and to thus expose the first circuit trace 111 along a length LR of the first rabbet 117.

The second PCB 120 includes a second circuit trace 121, first and second ground planes 122 and 123 at opposite sides of the second circuit trace 121, dielectric material 124 interposed between the second circuit trace 121 and the first and second ground planes 122 and 123 at the opposite sides of the second circuit trace 121 and a second end 125. The second circuit trace 121 can be formed of conductive material (e.g., copper, tin, etc.) and can be formed with a stripline shape 126 having a relative small thickness in the thickness dimension TD, a width in the width dimension WD that exceeds the relatively small thickness and a length in the length dimension LD that exceeds the width. The first and second ground planes 122 and 123 can be formed with conductive material (e.g., copper, tin, etc.) and can be substantially flat and planar. The dielectric material 124 electrically isolates the second circuit trace 121 between the first and second ground planes 122 and 123. The second end 125 is characterized in that an end of the first ground plane 122 and the dielectric material 124 between the first ground plane 122 and the second circuit trace 121 are recessed from respective corresponding ends of the second circuit trace 121 and the second ground plane 123 to thus form the second end 125 into a second rabbet 127 and to thus expose the second circuit trace 121 along a length LR of the second rabbet 127.

It is to be understood that the first and second PCBs 110 and 120 can also include additional ends formed as rabbets opposite or adjacent to the first end 115 and the second end 125, respectively. This will be described below with reference to FIG. 5.

With continued reference to FIGS. 1-4, the first and second ends 115 and 125 are mated in a shiplap joint 401 (see FIG. 4) to electrically couple the first circuit trace 111 and the second circuit trace 121.

As shown in FIGS. 1, 2 and 4, the stripline SNAP-RF connection interface 101 can further include conductive material 402 that is electrically interposed between the exposed length of the first circuit trace 111 at the first rabbet 117 (see FIGS. 1-3) and the exposed length of the second circuit trace 121 at the second rabbet 127 (see FIGS. 1-3). The conductive material 402 can include tin or another suitable material that is flown into and cured in the space between the first and second rabbets 117 and 127 during mating of the first and second ends 115 and 125 to increase electrical communication between the first circuit trace 111 and the second circuit trace 121.

As shown in FIG. 4, the stripline SNAP-RF connection interface 101 can further include one or more securing elements or effects. These include, but are not limited to, one or more fasteners 403 to fasten the first and second ends 115 and 125 together, one or more magnetic elements 404 to magnetically attract the first and second ends 115 and 125 together and an external mechanical force F that is directed so as to force the first and second ends 115 and 125 together.

With reference to FIG. 5, an RF circuit assembly 501 is provided and includes multiple stripline SNAP-RF connection interfaces 101 as described above with reference to FIGS. 1-4. As shown in FIG. 5, the RF circuit assembly 501 includes a plurality of PCBs 510 that are each connected to a neighboring PCB 510 by way of a stripline SNAP-RF connection interface 101. Each of the PCBs 510 includes one or more circuit traces 511, ground planes 512 at opposite sides of the one or more circuit traces 511, dielectric material (not shown) interposed between the one or more circuit traces 511 and the ground planes 512 and an end 513 formed as a rabbet at which the one or more circuit traces 511 are each exposed. The ends 513 of each of the PCBs 510 are mated in shiplap joints with ends 513 formed as substantially identical rabbets of neighboring PCBs 510 such that the corresponding one or more circuit traces 511 are electrically coupled.

The plurality of PCBs 510 can include first and second exterior PCBs 510₁ and 510₂ that each include lead terminals 521, first and second interior PCBs 510₃ and 510₄ that are mated with one another along stripline SNAP-RF connection interface 101₃₄ and include electrical devices 522, first intermediate PCBs 510₅, 510₆ and 510₇ and second intermediate PCBs 510₈, 510₉ and 510₁₀. First intermediate PCB 510₅ is mated with first exterior PCB 510₁ along stripline SNAP-RF connection interface 101₁₅, first intermediate PCB 510₇ is mated with first interior PCB 510₃ along stripline SNAP-RF connection interface 101₇₃ and first intermediate PCB 510₆ is mated with first intermediate PCB 510₅ along stripline SNAP-RF connection interface 101₅₆ and with first intermediate PCB 510₇ along stripline SNAP-RF connection interface 101₆₇. Second intermediate PCB 510₈ is mated with second exterior PCB 510₂ along stripline SNAP-RF connection interface 101₂₈, second intermediate PCB 510₁₀ is mated with second interior PCB 510₄ along stripline SNAP-RF connection interface 101₁₀₄ and second intermediate PCB 510₉ is mated with second intermediate PCB 510₈ along stripline SNAP-RF connection interface 101₈₉ and with second intermediate PCB 510₁₀ along stripline SNAP-RF connection interface 101₉₁₀. Circuit traces proceed from the lead terminals 521 and external inputs through each of the PCBS 510 and each of the stripline SNAP-RF connection interfaces 101 to the electrical devices 522.

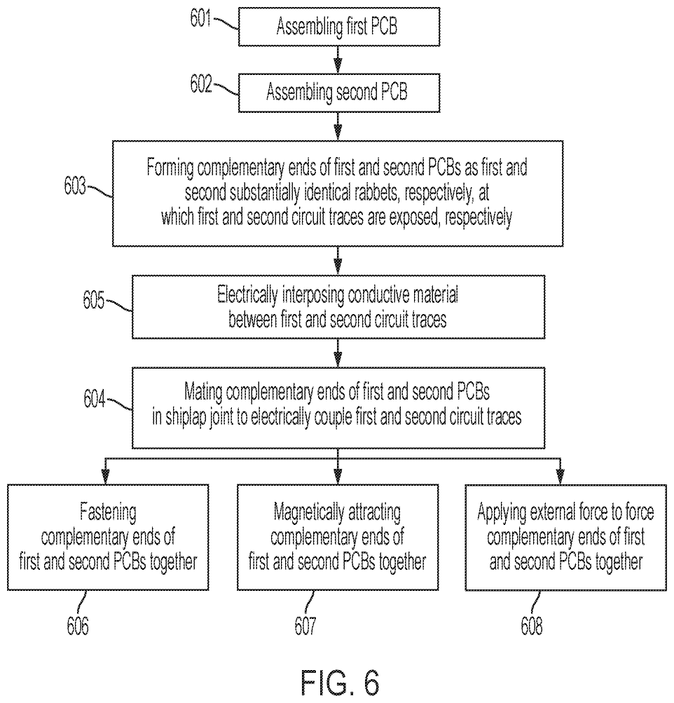

With reference to FIG. 6, a method of assembling a stripline SNAP-RF connection interface as described above is provided. As shown in FIG. 6, the method includes assembling a first PCB to include a first circuit trace, ground planes at opposite sides of the first circuit trace and dielectric material interposed between the first circuit trace and the ground planes 601 and assembling a second PCB to include a second circuit trace, ground planes at opposite sides of the second circuit trace and dielectric material interposed between the second circuit trace and the ground planes 602. The method further includes forming complementary ends of the first and second PCBs as first and second substantially identical rabbets, respectively, at which the first and second circuit traces are exposed, respectively 603 and mating the complementary ends of the first and second PCBs in a shiplap joint to electrically couple the first and second circuit traces 604.

In accordance with embodiments, the method can further include electrically interposing conductive material between the first and second circuit traces 605 prior to or during the mating of operation 604 and one or more of fastening the complementary ends of the first and second PCBs together 606, magnetically attracting the complementary ends of the first and second PCBs together 607 and applying an external mechanical force to force the complementary ends of the first and second PCBs together 608.

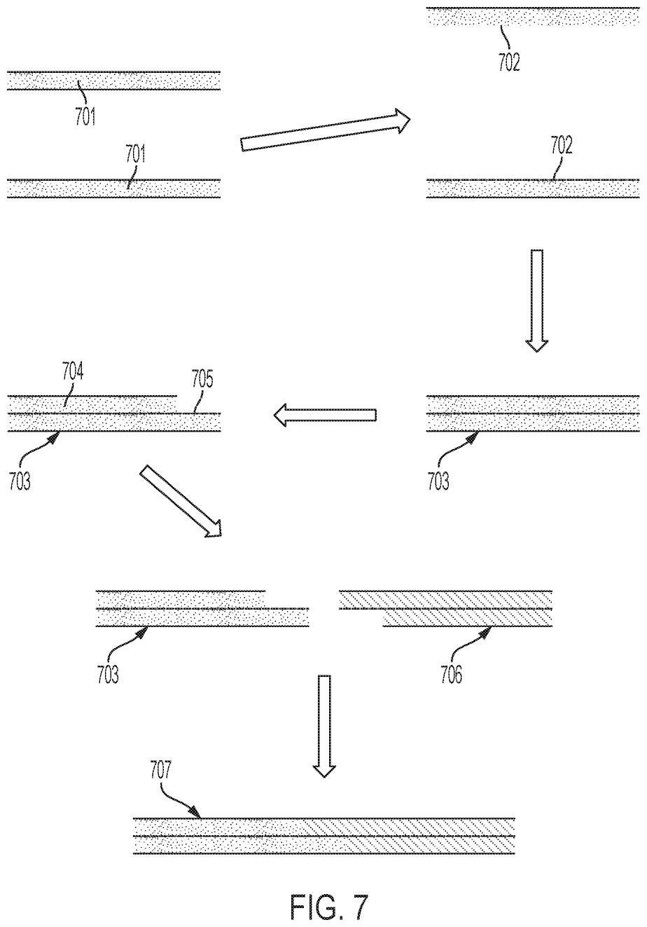

With reference to FIG. 7, the method of FIG. 6 will be described in further detail. As shown in FIG. 7, two single-layer, double clad dielectric substrates 701 are provided at an initial time and etched or milled to create a stripline circuit architecture 702 in each. The etched or milled substrates are then bonded using conventional PCB lamination processes into a bonded formation board 703. The upper substrate 704 of the bonded formation board 703 is then milled to expose the copper trace 705 and the exposed copper trace 705 is tinned to prevent corrosion. At this point, a second bonded formation board 706 with a reversed orientation is gathered and mated with the bonded formation board 703 such that the tinned exposed copper traces 705 are brought into electrical contact or coupling and to thus form a mated configuration 707. Although not shown, pressure can be applied to the mated configuration 707 by way of fasteners, magnetic elements and external forces.

Technical effects and benefits of the present invention are the provision of a low-cost stripline SNAP-RF connection that can be made with reduced process steps and equipment requirements as compared to traditional connectors, can be relatively easily integrated into PCB manufacturing processes and can be relatively easily assembled and maintained in the field, has excellent electrical performance and a reduced/zero height profile and exhibits increased connection densities as compared to traditional RF connectors.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated.

While the preferred embodiments to the invention have been described, it will be understood that those skilled in the art, both now and in the future, may make various improvements and enhancements which fall within the scope of the claims which follow. These claims should be construed to maintain the proper protection for the invention first described.

What is claimed is:

1. A stripline radio-frequency (RF) connection interface, comprising:
a first printed circuit board (PCB) comprising a first trace, ground planes at opposite sides of the first trace, dielectric material interposed between the first trace and the ground planes and a first end formed as a first rabbet at which the first trace is exposed; and
a second PCB comprising a second trace, ground planes at opposite sides of the second trace, dielectric material interposed between the second trace and the ground planes and a second end formed as a second rabbet substantially identical to the first rabbet at which the second trace is exposed,
the first and second ends being mated in a shiplap joint to electrically couple the first and second traces.

2. The stripline RF connection interface according to claim 1, wherein the ground planes of the first and second PCBs each comprise conductive material.

3. The stripline RF connection interface according to claim 1, wherein the first and second traces are each formed as striplines.

4. The stripline RF connection interface according to claim 1, further comprising a conductive material electrically interposed between the first and second traces.

5. The stripline RF connection interface according to claim 1, further comprising one or more fasteners to fasten the first and second ends together.

6. The stripline RF connection interface according to claim 1, further comprising one or more magnetic elements to magnetically attract the first and second ends together.

7. The stripline RF connection interface according to claim 1, wherein an external mechanical force forces the first and second ends together.

8. A radio-frequency (RF) circuit assembly, comprising:
a plurality of printed circuit boards (PCBs),
each PCB of the plurality of PCBs comprising a trace, ground planes at opposite sides of the trace, dielectric material interposed between the trace and the ground planes and an end formed as a rabbet at which the trace is exposed,
the end of each PCB of the plurality of PCBs being mated in a shiplap joint with an end formed as a substantially identical rabbet of a neighboring PCB such that the corresponding traces are electrically coupled.

9. The RF circuit assembly according to claim 8, wherein the plurality of PCBs comprises:
first and second exterior PCBs comprising lead terminals;
first and second interior PCBs mated with one another and comprising electrical devices; and
first and second intermediate PCBs mated in sequence with the first and second exterior PCBs, respectively, with one another, respectively, and with the first and second interior PCBs, respectively.

10. The RF circuit assembly according to claim 8, wherein the ground planes of each PCB of the plurality of PCBs each comprise conductive material.

11. The RF circuit assembly according to claim 8, wherein the trace of each PCB of the plurality of PCBs is formed as a stripline.

12. The RF circuit assembly according to claim 8, further comprising a conductive material electrically interposed between the traces of neighboring PCBs.

13. The RF circuit assembly according to claim 8, further comprising one or more fasteners to fasten respective ends of neighboring PCBs together.

14. The RF circuit assembly according to claim 8, further comprising one or more magnetic elements to magnetically attract respective ends of neighboring PCBs together.

15. The RF circuit assembly according to claim 8, wherein an external mechanical force forces respective ends of neighboring PCBs together.

16. A method of assembling a stripline radio-frequency (RF) connection interface, the method comprising:
assembling a first printed circuit board (PCB) to comprise a first trace, ground planes at opposite sides of the first trace and dielectric material interposed between the first trace and the ground planes;
assembling a second PCB to comprise a second trace, ground planes at opposite sides of the second trace and dielectric material interposed between the second trace and the ground planes;
forming complementary ends of the first and second PCBs as first and second substantially identical rabbets, respectively, at which the first and second traces are exposed, respectively; and
mating the complementary ends of the first and second PCBs in a shiplap joint to electrically couple the first and second traces.

17. The method according to claim 16, further comprising electrically interposing conductive material between the first and second traces.

18. The method according to claim 16, further comprising fastening the complementary ends of the first and second PCBs together.

19. The method according to claim 16, further comprising magnetically attracting the complementary ends of the first and second PCBs together.

20. The method according to claim 16, further comprising applying an external mechanical force to force the complementary ends of the first and second PCBs together.
